(19) United States
(12) Patent Application Publication
(10) Pub. No.: US 2011/0280407 A1
(43) Pub. Date: Nov. 17, 2011

(54) Compressor Based Dynamic Bass Enhancement with EQ

(76) Inventors: Scott Skinner, Westborough, MA (US); Christopher M. Hanna, Arlington, MA (US)

(21) Appl. No.: 12/987,056

(22) Filed: Jan. 7, 2011

Related U.S. Application Data
(63) Continuation-in-part of application No. 12/619,653, filed on Nov. 16, 2009.
Application No. 12/619,653 is a continuation-in-part of application No. 12/619,655, filed on Nov. 16, 2009.
(60) Provisional application No. 61/293,005, filed on Jan. 7, 2010.
(60) Provisional application No. 61/114,684, filed on Nov. 14, 2008.
(60) Provisional application No. 61/114,684, filed on Nov. 14, 2008.
(60) Provisional application No. 61/114,777, filed on Nov. 14, 2008.
(60) Provisional application No. 61/114,777, filed on Nov. 14, 2008.

(51) Int. Cl. H03G 5/00; H04R 5/00

(52) U.S. Cl. 381/28; 381/99

(57) ABSTRACT

A system for and method of enhancing the low frequency response of a loudspeaker for relatively low input level audio signals and protect the loudspeaker for relatively high input level audio signals is disclosed. The system comprises: a crossover network configured so separate an audio input signal into at least two frequency bands including a low frequency band; and a signal compressor responsive to the energy level of the low frequency portion of an input audio signal in the low frequency band and configured to provide amplification gain on the low frequency portion of the input signal when the energy level of the low frequency portion of the input signal is relatively low so as to enhance the low frequency response of the loudspeaker, and attenuation of the low frequency portion of the input signal when the energy level of the low frequency portion of the input signal is relatively high so as to protect the loudspeaker from being overdriven. The system is configurable so that it can be used to enhance the loudspeakers of audio and video play devices such as televisions and computers.

### CROSS-REFERENCE TO RELATED APPLICATION

This application is based upon and claims priority to U.S. provisional patent application 61/293,005, entitled “Compressor Based Dynamic Bass Enhancement,” filed on Jan. 7, 2010 in the names of Scott Skinner and Chris Hanna, and assigned to the present assignee (Attorney docket number 056233-0438 (THAT-33PR)).

This application is also a continuation-in-part application of U.S. patent application Ser. No. 12/619,653, entitled “Dynamic Volume Control and Multi-Spatial Processing Protection,” filed Nov. 16, 2009 in the names of Christopher M. Hanna, Gregory Benulis and Scott Skinner, and assigned to the present assignee (Attorney docket number 056233-0427 (THAT-0026)), and U.S. patent application Ser. No. 12/619,655, entitled “Dynamic Volume Control and Multi-Spatial Processing Protection”, filed Nov. 16, 2009 in the names of Christopher M. Hanna and Gregory Benulis, and assigned to the present assignee (Attorney docket number 056233-0428 (THAT-0027)) (the “Co-pending Applications”), both of the Co-pending Applications claiming priority from U.S. Provisional Application Nos. 61/114,684 filed on 14 Nov. 2008 in the names of Christopher M. Hanna, Gregory Benulis and Scott Skinner; and 61/114,777 filed on 14 Nov. 2008 in the names of Christopher M Hanna and Gregory Benulis.

The entire content of each of these applications is incorporated herein by reference.

### BACKGROUND

1. Technical Field

This disclosure relates to audio reception and playback, and more particularly to systems for and techniques of enhancing the perceived bass response of inexpensive speakers typically incorporated into audio and video reception and playback devices such as televisions and computers.

2. Description of Related Art

Most consumers are much more sensitive to the quality of visual displays than they are to sound quality. In order to keep cost at a minimum, consumer electronics manufacturers of audio and video systems, such as televisions and computers, thus are more likely to install small, inexpensive speakers in the systems. These speakers typically have poor low frequency (bass) response and become more prone to distortion as the audio frequency moves further below the speaker's low frequency resonance point. For those consumers who are more discerning, the audio and video reception and playback systems are usually configured so that additional speakers can be connected to the audio and video reception and playback systems for improving the quality of the audio portion of any programming.

### SUMMARY

The disclosure describes a system for and technique of improving the perceived bass response of such internally mounted speakers of a system that receives and plays back audio programming. The disclosed system and technique also provides enhancement of the amount of bass so that sound appears to be emanating from higher quality, wider bandwidth speakers, without requiring the connection of additional speakers,

More specifically, in accordance with one aspect, a system is provided for enhancing the low frequency response of a loudspeaker for relatively low input level audio signals and protect the loudspeaker for relatively high input level audio signals. The system comprises: a crossover network configured so as to separate an audio input signal into at least two frequency bands including a low frequency band; and a signal compressor responsive to the energy level of the low frequency portion of an input audio signal in the low frequency band and configured to provide amplification gain on the low frequency portion of the input signal when the energy level of the low frequency portion of the input signal is relatively low so as to enhance the low frequency response of the loudspeaker, and attenuation of the low frequency portion of the input signal when the energy level of the low frequency portion of the input signal is relatively high so as to protect the loudspeaker from being overdriven.

In accordance with other aspects, the crossover network is configured to separate the audio signal into two frequency bands, wherein parameters of the system are configurable to optimize for a given speaker characteristic or listener preference. The configurable parameters include one or more of the following: crossover frequency, compression ratio, maximum allowable gain, high pass filter cutoff frequency, and target level. In one embodiment, the compressor includes an RMS based level detector for generating a signal representing the energy level of the low frequency portion of the input audio signal. In accordance with another embodiment, a summing block is provided so as to provide a summed signal as a function of the compressed output of the signal compressor signal provided in each remaining frequency band. A high pass filter can be configured to respond to the summed signal and limit the lowest frequency energy applied to the loudspeaker. Further, a peak limiter can be configured to respond to the summed signal and limit the maximum peak level of signal energy applied to loudspeaker. It should be obvious that the peak limiter could also be placed, in the low band, before the summer and respond to the compressor output. The system can further include a static equalizer configured to respond to the summed signal, the static equalizer including a lower limit greater than or equal to the crossover frequency of the cross over network so that the static equalizer, combined with the compressor, operates as a partially dynamic equalizer. In accordance with one embodiment, the system is configured to enhance the low frequency response of at least two loudspeakers for left and right channel stereo play, the crossover network is configured to separate each left and right channel audio input signals into at least two frequency bands including a low frequency band; and the signal compressor is responsive to the energy level of the low frequency portion of each of the left and right audio input signals in the low frequency band and configured to provide amplification gain on the low frequency portion of each of the left and right channel audio input signals when the energy level of the low frequency portion of each of the signals is relatively low so as to enhance the low frequency response of each of the loudspeakers, and provide attenuation of the low frequency portion of each of the left and right channel audio input signals when the energy level of the low frequency portion of each of the signals is relatively high so as to protect each loudspeaker from being overdriven. Finally, in accordance with another embodiment, the system can include a pair of summing blocks for providing a pair of summed signals as a function of the compressed output signal of the signal compressor of the left channel and the corresponding signals of remaining frequency bands of the left channel, and the compressed output signal of the signal compressor of the right channel and the corresponding signals of the remaining bands of the right channel. The system can further include a signal summer configured to provide a summed compressed signal representing the sum of the compressed output signals of the signal compressor of the left and right channels, and at least two summing blocks for providing left and right channel summed signals as a function of the summed compressed signal and the portion of each left and right channel signal provided in each remaining frequency band.

In accordance with another aspect, a two-band compressor based architecture for use with a loudspeaker is provided. The architecture is configurable as a volume leveler, bass enhancer and speaker protection device.

In accordance with another aspect, a method of enhancing the low frequency response of a loudspeaker is provided for relatively low input level audio signals and protecting the loudspeaker for relatively high input level audio signals. The method comprises: separating an audio input signal into at least two frequency bands including a low frequency band; and compressing the low frequency portion of an input audio signal in the low frequency band so as to provide amplification gain on the low frequency portion of the input signal when the energy level of the low frequency portion of the input signal is relatively low so as to enhance the low frequency response of the loudspeaker, and provide attenuation of the low frequency portion of the input signal when the energy level of the low frequency portion of the input signal is relatively high so as to protect the loudspeaker from being overdriven.

These, as well as other components, steps, features, objects, benefits, and advantages, will now become clear from a review of the following detailed description of illustrative embodiments, the accompanying drawings, and the claims.

### BRIEF DESCRIPTION OF DRAWINGS

The drawings disclose illustrative embodiments. They do not set forth all embodiments. Other embodiments may be used in addition or instead. Details which may be apparent or unnecessary may be omitted to save space or for more effective illustration. Conversely, some embodiments may be practiced without all of the details which are disclosed. When the same numeral appears in different drawings, it refers to the same or like components or steps. In the drawings:

FIG. 1 is a block diagram of one embodiment of a base enhancement system configured so as to improve the perceived bass response, and tonal balance of speakers of the type that are usually mounted internally in systems which include that ability to receive and play audio programming as well as enhance the amount of bass reproduced so that sound appears to be emanating from higher quality, wider bandwidth speakers;

FIG. 2 is a block diagram of the low band compressor shown and described with respect to FIGS. 1 and 5;

FIG. 3 is an example of a typical frequency response plot of one of the bass enhanced outputs (Lo or Ro in FIG. 1) for different input levels;

FIG. 4 is an example of the actual measured output of a sample set of small speakers of the type incorporated into audio and video systems; and

FIG. 5 is a block diagram of an embodiment of a bass enhancement system configured to sum the low band signal to mono.

### DETAILED DESCRIPTION OF ILLUSTRATIVE EMBODIMENTS

Illustrative embodiments are now discussed. Other embodiments may be used in addition or instead. Details which may be apparent or unnecessary may be omitted to save space or for a more effective presentation. Conversely, some embodiments may be practiced without all of the details which are disclosed.

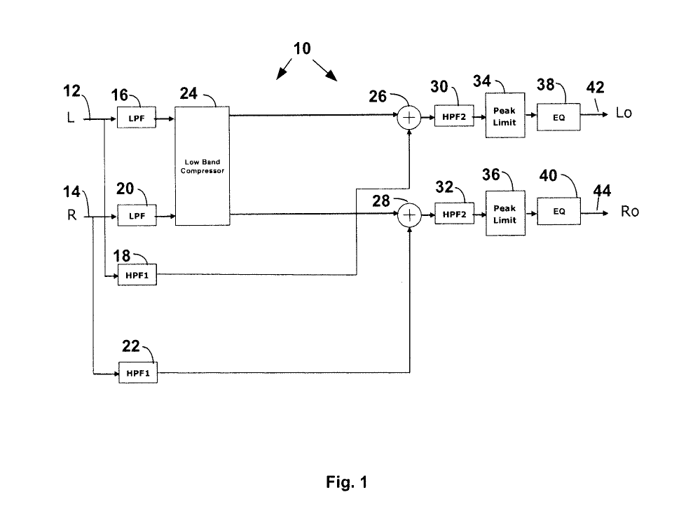

FIG. 1 is a block diagram showing one example of a compressor based bass enhancement system for use in enhancing the bass response of a speaker system. The base enhancement system 10 includes inputs 12 and 14 configured to respectively receive the left and right channel signals of an audio stereo program. Left channel input 12 is coupled to an input of LPF (low pass filter) 16 and an input of HPF1 (high pass filter) 18. Right channel input 14 is coupled to an input of LPF 20 and an input of HPF1 22. The outputs of LPFs 16 and 20 are both connected to a low band compressor 24 configured to compress each signal and provide the compressed signal at a corresponding output of the compressor, wherein the left channel signal is coupled to summing block 26, while the right channel is coupled to summing block 28. Compressing the portion of the audio signal applied to the compressor results in amplifying small signals and attenuating large signals passed through the compressor while applying unity gain for signals somewhere in the middle. The summing blocks 26 and 28 are also coupled to the outputs of HPF1 and HPF2 30 and 32, respectively, so that block 26 provides a summed signal as a function of the left channel signal output of the compressor 24 and the left channel signal output of HPF1 18. Similarly, block 28 provides a summed signal as a function of the right channel signal output of the compressor 24 and the right channel signal output of HPF1 22. The left channel summed signal output of the block 26 is then applied to the input of a second HPF2 30, and the right channel summed signal output of block 28 is applied to the input of the second HPF 32. The output of each filter HPF2 30 and HPF2 32 is applied to a respectively peak limiter 34 and 36. The latter limits the peak levels of the respective signals applied to the limiters. The output of limiter 34 is applied to equalizer (EQ) 38 configured to provide at least a two band equalization function on the signal applied to the equalizer. EQ 38 provides the left channel output signal Lo at output 42. Similarly, the output of limiter 36 is applied to EQ 40 configured to provide at least a two band equalization function on the signal applied to the equalizer. EQ 40 provides the left channel output signal Ro at output 44. In accordance with one embodiment, each EQ38 and 40 is a static equalizer configured to respond to the signal applied at its input and establish a lower limit above the crossover frequency of the cross over network formed by filters 16, 18, 20 and 22 so that each static equalizer EQ 38 and 40 operates as a partially dynamic equalizer.

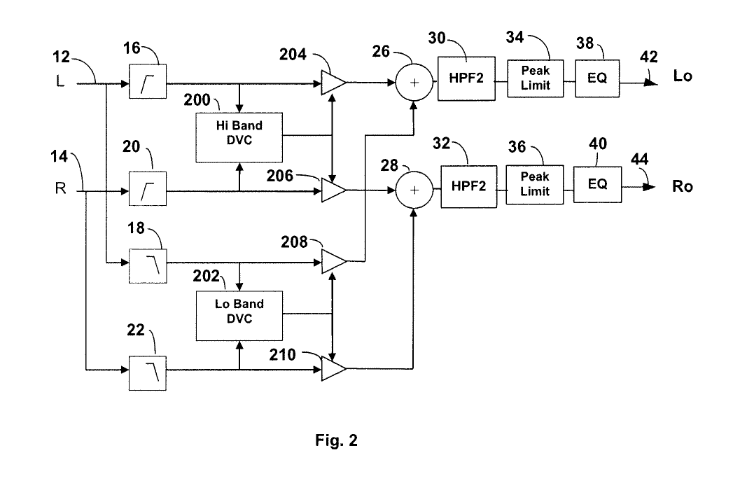

The LPFs 16 and 18, HPF1s 20 and 22, low band compressor 24 and summing blocks 26, 28 thus combine to form a two-band crossover based architecture. The architecture of the low band compressor 24 can be similar to the dynamic volume control arrangement shown and described in the Co-pending Applications. For example as shown in FIG. 2, the outputs of the left channel HPF 16 and right channel HPF 18 are applied to the Hi Band DVC 200, while the outputs of the left channel LPF 18 and right channel LPF 22 are applied to the inputs of Lo Band DVC 202. The output of Hi Band DVC 200 controls the gain of amplifier 204 which receives the left channel output of HPF 16, and controls the gain of amplifier 206 which receives the right channel output of right channel HPF 20. The outputs of amplifiers 204 and 206 are respectively applied to the summing blocks 26 and 28, respectively. Similarly, the output of Lo Band DVC 202 controls the gain of amplifier 208 which receives the left channel output of LPF 18, and the gain of amplifier 210 which receives the right channel output of LPF 22. The outputs of amplifiers 208 and 210 are respectively applied to the summing blocks 26 and 28. It should be noted that by changing the compression ratio of the Hi Band DVC 200 to 1:1 so that the gain applied to amplifiers 204 and 206 is unity gain, the outputs of the left channel HPF 16 and right channel HPF 18 pass through the amplifiers to the respective summing blocks 26 and 28 unchanged. Further, the Lo Band DVC 202 can be adjusted for various parameters including the change target level, compression ratio, attack time constant and release time constant to model the dynamic bass boost function all tailored to the specific speaker systems receiving the Lo and Ro outputs. In one embodiment the Lo Band DVC and Hi Band DVC each include an RMS level detector for use in controlling the gains of the corresponding amplifiers 204, 206 and amplifiers 208 and 210. Further, amplifiers 204, 206, 208 and 210 can each be in the form of voltage control amplifiers. It should be appreciated that other architectures and components can be used. For example, one can use other types of signal compressors as well as other types of level detectors including peak and averaging detectors.

Referring again to FIG. 1, the compressor outputs of compressor 24 are summed with the high band energy provided at the outputs of HPF1 18 and 22 so as to complete the crossover network. HPF2 30 and 32 limit the lowest frequency that reaches each of the loudspeakers. This prevents the lowest frequencies that cannot be reasonably reproduced from reaching the speaker driver. Occasionally, the compressor may briefly provide too much gain (overshoot) to the input low band audio signal. The Peak limiter is provided to protect the speaker from this phenomenon. The peak limiter is positioned after the crossover network to limit the combined low and high band audio peaks to prevent overdriving the speaker. The Equalizer (EQ) can be used to flatten the speaker frequency response at those frequencies above the low band. The combination of improved tonal balance (EQ) and improved low frequency response (compressor based dynamic boost) can make a dramatic improvement in the fidelity of small speakers.

The compressor target level is set relatively high when compared to typical input signal bass frequency levels. This results in the compressor typically adding gain to the left and right low band audio input signals in order to maintain the desired low band output level. The amount of gain is controlled both by the compressor target level and the compression ratio. The amount of bass enhancement can be increased by increasing the target compressor target level. The amount of bass enhancement can be decreased by decreasing the compressor target level. The amount of bass enhancement is dynamic since the gain (or attenuation) applied to the left and right input audio is a function of the input level. In one implementation the compressor has a maximum gain limit. This limit helps minimize the compressor's affect on the tonal balance of the audio. In addition to bass enhancement, the speakers are also protected from high levels of low-band energy. The compressor will attenuate the input left and right audio when the level exceeds the compressor target level. The compressor target level is typically adjusted to a level just below where the low band audio begins to distort the speaker. It should be clear that the parameters such as crossover frequency, target level, HPF2 cutoff frequency, peak limit, maximum gain limit and EQ configuration can be adjusted, for optimal performance, for a given speaker.

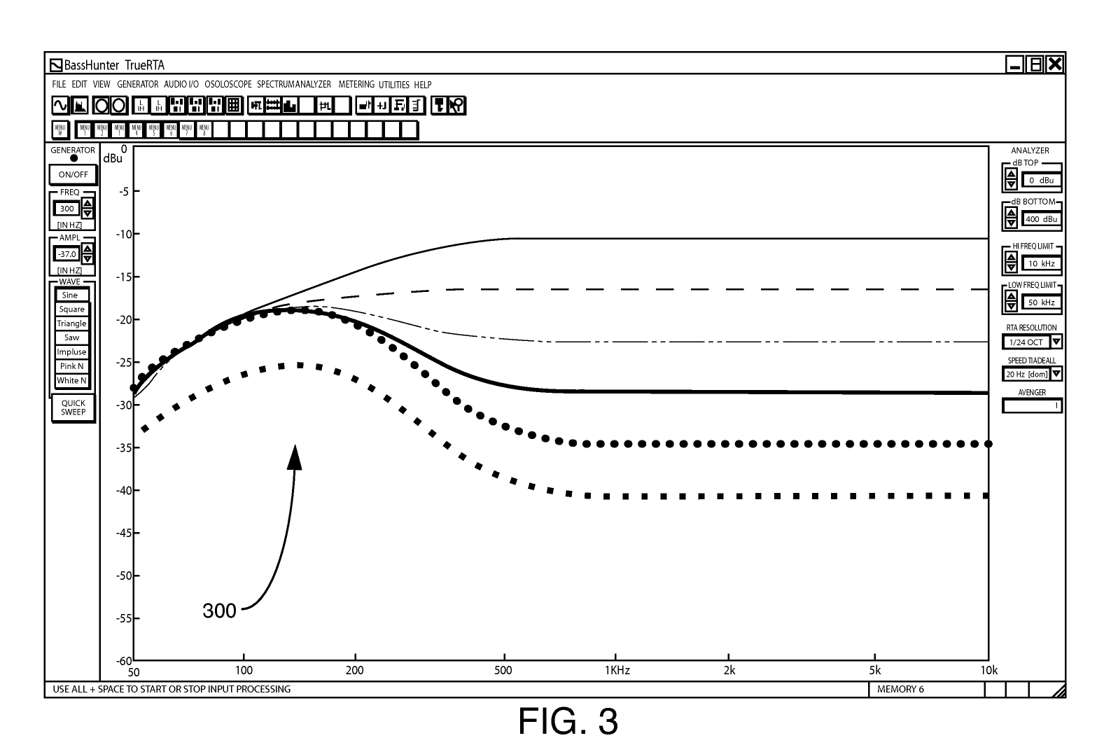

FIG. 3 shows one example of a frequency response plot of one of the bass enhancer outputs (Lo or Ro in FIG. 1) for different input levels. The input level is increased in 6 dB steps. The excitation is a quick sine wave sweep (20-20 KHz in less than a second). EQ 38 and 40 were bypassed when this plot was generated.

The high band of the FIG. 3 response remains flat since it is passed unmodified. It exhibits the 6 dB level change of each sweep. The low band is boosted proportional to the input level. Reference is made to the level changes with each sweep around 150 Hz, indicated in FIG. 2 at 300. In the low band the first two lowest input levels exhibit significant boost. The fact that the two lowest level curves are still about 6 dB apart, in the low band, indicates that the compressor 24 has achieved maximum gain. At these input levels the compressor 24 acts like a fixed boost. As the input level continues to increase, less boost is added as the input level approaches the compressor target level. Eventually, the frequency response is flat. As the input level increases, compressor 24 introduces low band attenuation in order to protect the speaker from being driven at levels which would cause high distortion. When the target level is chosen slightly below the maximum low frequency drive level, the compressor based bass enhancement system provides as much boost as possible without driving the speaker into distortion. When this feature is combined with high band EQ (to flatten the speaker high band response) small inexpensive speakers exhibit much improved fidelity.

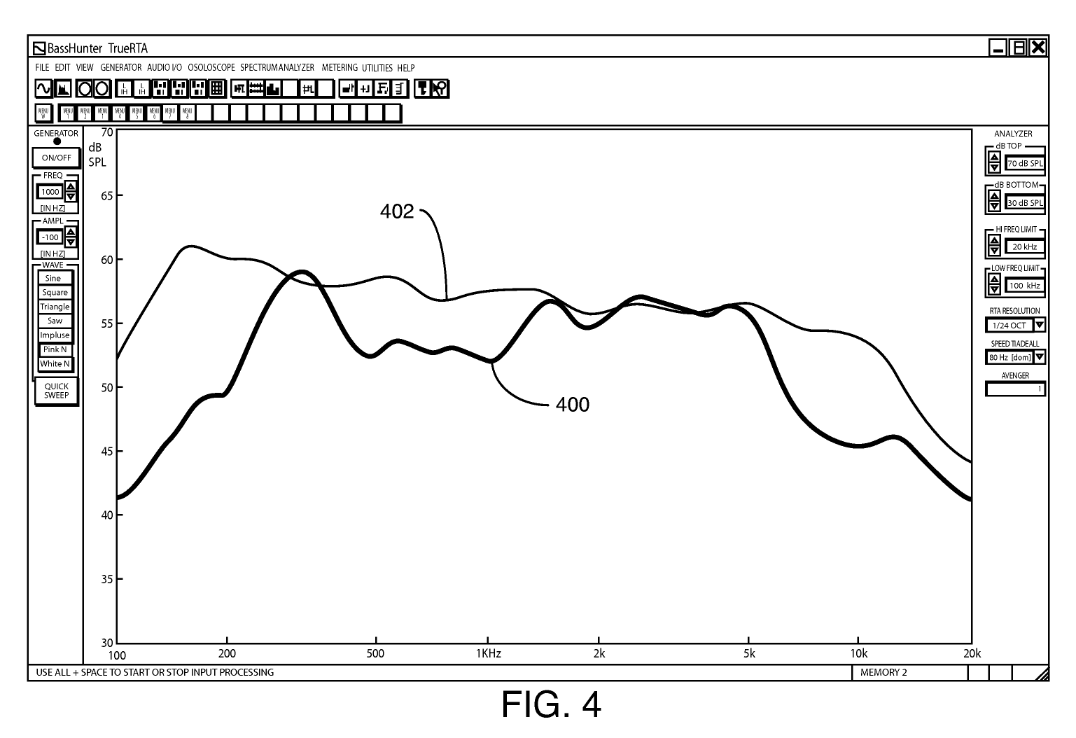

FIG. 4 shows the actual measured output of a sample set of small speakers. The lowest level input response shown at 400 represents the speakers without EQ or low band compressor processing. The speakers have limited bandwidth and do not have a flat response. The next response at 402 represents the same input level after low band bass enhancement and high band EQ. The response is now relatively flat from 150 Hz to 10 KHz.

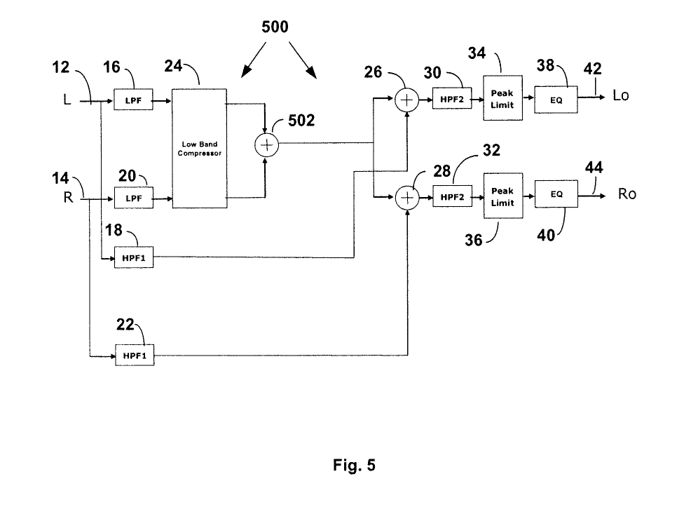

In some instances it is desirable to provide bass enhancement equally to both speakers. FIG. 5 shows a version of the bass enhancement system 500 which includes a summing block 502 configured to sum the low band signals of each channel to provide a monophonic signal, which in turn is applied to each of summing blocks 26 and 28. After the compressor, the L and R signals are attenuated by 6 dB and summed together to create a mono low band signal. This distributes the bass energy equally between the two speakers and can result in more overall perceived bass.

The components, steps, features, objects, benefits and advantages which have been discussed are merely illustrative. None of them, nor the discussions relating to them, are intended to limit the scope of protection in any way. Numerous other embodiments are also contemplated. These include embodiments which have fewer, additional, and/or different components, steps, features, objects, benefits and advantages. These also include embodiments in which the components and/or steps are arranged and/or ordered differently.

For example, while the system has been described as employing two frequency bands, the system can employ any number of bands when additional signal processing of individual bands is desirable

Unless otherwise stated, all measurements, values, ratings, positions, magnitudes, sizes, and other specifications which are set forth in this specification, including in the claims which follow, are approximate, not exact. They are intended to have a reasonable range which is consistent with the functions to which they relate and with what is customary in the art to which they pertain.

All articles, patents, patent applications, and other publications which have been cited in this disclosure are hereby incorporated herein by reference.

The phrase “means for” when used in a claim is intended to and should be interpreted to embrace the corresponding structures and materials which have been described and their equivalents. Similarly, the phrase “step for” when used in a claim is intended to and should be interpreted to embrace the corresponding acts which have been described and their equivalents. The absence of these phrases in a claim mean that the claim is not intended to and should not be interpreted to be limited to any of the corresponding structures, materials, or acts or to their equivalents.

Nothing which has been stated or illustrated is intended or should be interpreted to cause a dedication of any component, step, feature, object, benefit, advantage, or equivalent to the public, regardless of whether it is recited in the claims.

The scope of protection is limited solely by the claims which now follow. That scope is intended and should be interpreted to be as broad as is consistent with the ordinary meaning of the language which is used in the claims when interpreted in light of this specification and the prosecution history which follows and to encompass all structural and functional equivalents.

The invention claimed is:

1. A system for enhancing the low frequency response of a loudspeaker for relatively low input level audio signals and protect the loudspeaker for relatively high input level audio signals, the system comprising:
a crossover network configured so as to separate an audio input signal into at least two frequency bands including a low frequency band; and
a signal compressor responsive to the energy level of the low frequency portion of an input audio signal in the low frequency band and configured to provide amplification gain on the low frequency portion of the input signal when the energy level of the low frequency portion of the input signal is relatively low so as to enhance the low frequency response of the loudspeaker, and provide attenuation of the low frequency portion of the input signal when the energy level of the low frequency portion of the input signal is relatively high so as to protect the loudspeaker from being overdriven.

2. A system according to claim 1, wherein the crossover network is configured to separate the audio signal into two frequency bands.

3. A system according to claim 1, wherein parameters of the system are configurable to optimize for a given speaker characteristic or listener preference.

4. A system according to claim 3, wherein the configurable parameters include one or more of the following: crossover frequency, compression ratio, maximum allowable gain, high pass filter cutoff frequency and target level.

5. A system according to claim 1 where the compressor includes an RMS based level detector for generating a signal representing the RMS energy level of the low frequency portion of the input audio signal.

6. A system according to claim 1, further including a summing block for providing a summed signal as a function of the compressed output of the signal compressor signal provided in each of any remaining frequency bands.

7. A system according to claim 6, further including a high frequency filter configured to respond to the summed signal and limit the lowest frequency energy applied to the loudspeaker.

8. A system according to claim 6, further including a peak limiter configured to respond to the summed signal and limit the maximum peak level of signal energy applied to loudspeaker

9. A system according to claim 6, further including a peak limiter configured, before the summing block, to respond to the compressed output of the signal compressor and limit the maximum peak level of signal energy in the low frequency band only.

10. A system according to claim 6, further including a static equalizer configured to respond to the summed signal and including a lower limit greater than or equal to the crossover frequency of the cross over network so that the static equalizer, when combined with the low band compressor, operates as a partially dynamic equalizer.

11. A system according to claim 1, wherein
the system is configured to enhance the low frequency response of at least two loudspeakers for left and right channel stereo play;
the crossover network is configured to separate each left and right channel audio input signals into at least two frequency bands including a low frequency band; and
the signal compressor is responsive to the energy level of the low frequency portion of each of the left and right audio input signals in the low frequency band and configured to provide amplification gain on the low frequency portion of each of the left and right channel audio input signals when the energy level of the low frequency portion of each of the signals is relatively low so as to enhance the low frequency response of each of the loudspeakers, and provide attenuation of the low frequency portion of each of the left and right channel audio input signals when the energy level of the low frequency portion of each of the signals is relatively high so as to protect each loudspeaker from being overdriven.

12. A system according to claim 11, wherein further including a pair of summing blocks for providing a pair of summed signals as a function of the compressed output signal of the signal compressor of the left channel and the corresponding signals of remaining frequency bands of the left channel, and the compressed output signal of the signal compressor of the right channel and the corresponding signals of the remaining bands of the right channel.

13. A system according to claim 11, wherein further a signal summer configured to provide a summed compressed signal representing the sum of the compressed output signals of the signal compressor of the left and right channels, and at least two summing blocks for providing left and right channel summed signals as a function of the summed compressed signal and the portion of each left and right channel signal provided in each remaining frequency band.

14. A two-band compressor based architecture for use with a loudspeaker, architecture being configurable as a volume leveler, bass enhancer and speaker protection device.

15. A method of enhancing the low frequency response of a loudspeaker for relatively low input level audio signals and protect the loudspeaker for relatively high input level audio signals, the method comprising:
separating an audio input signal into at least two frequency bands including a low frequency band; and
compressing the low frequency portion of an input audio signal in the low frequency band so as to provide amplification gain on the low frequency portion of the input signal when the energy level of the low frequency portion of the input signal is relatively low so as to enhance the low frequency response of the loudspeaker, and provide attenuation of the low frequency portion of the input signal when the energy level of the low frequency portion of the input signal is relatively high so as to protect the loudspeaker from being overdriven.

16. A method according to claim 15, further including providing a pair of summed signals as a function of the compressed output signal of the signal compressor of the left channel and the corresponding signals of remaining frequency bands of the left channel, and the compressed output signal of the signal compressor of the right channel and the corresponding signals of the remaining bands of the right channel.

17. A system according to claim 15, wherein further providing a summed compressed signal representing the sum of the compressed signals of the left and right channels, and providing left and right channel summed signals as a function of the summed compressed signal and the portion of each left and right channel signal provided in each remaining frequency band.
